(19) United States
(12) Patent Application Publication
(10) Pub. No.: US 2011/0222229 A1
(43) Pub. Date: Sep. 15, 2011

(54) ELECTRONIC DEVICE

(75) Inventor: Takeshi MORI, Osaka (JP)

(73) Assignee: PANASONIC CORPORATION, Osaka (JP)

(21) Appl. No.: 13/044,061

(22) Filed: Mar. 9, 2011

(30) Foreign Application Priority Data
Mar. 11, 2010 (JP) 2010-054818

(51) Int. Cl. G06F 1/16; H05K 5/00

(52) U.S. Cl. 361/679.09; 361/679.01

(57) ABSTRACT

To obtain an electronic device having a configuration in which breaking of a connection wire and the like are not likely to occur even if a first casing is pivoted with respect to a second casing regularly. A first casing 1 including a first electric circuit and a second casing 2 including a second electric circuit are pivotably integrated by a hinge mechanism (6, 9), and a connection wire 5 that connects the first electric circuit with the second electric circuit is led from the inside of the second casing 2 into a hinge portion in which the hinge mechanism (6, 9) is housed, and in the hinge portion, the connection wire forms a detour portion 11 having a first direction component 11a that is oriented in a first direction parallel to a pivot axis x of the hinge mechanism (6, 9) and a second direction component 11b that is oriented in a second direction parallel to the pivot axis x and opposite to the first direction, and thereafter is led out of the hinge portion into the first casing.

### BACKGROUND OF THE INVENTION

1. Field of the Invention

The present invention relates to an electronic device in which a first casing is attached by a hinge mechanism so as to be pivotable with respect to a second casing, and in particular to an electronic device having a structure in which damage is not likely to be caused to a connection wire that connects an electric circuit in the first casing with an electric circuit in the second casing when the first casing is pivoted with respect to the second casing using the hinge mechanism.

2. Description of Related Art

In recent years, so-called mobile use electronic devices such as notebook computers, PDAs (personal digital assistants), mobile phones, and portable game devices are becoming widespread. There are many cases where, in such mobile use electronic devices, a body portion and a display portion are constituted as separate casings, and the display portion is pivotably attached by a hinge mechanism, as a cover portion of the body portion. By adopting such a configuration, the display area of the display portion can be increased to almost the same size as the surface area of the body portion, and also an information input/output terminal mechanism such as a keyboard and input buttons formed on the surface of the body portion and the display face of a display panel can be protected at the same time since the display portion serves as the cover portion of the body portion when the electronic device is not used.

However, if an electronic device is constituted by the display portion and the body portion that are separate casings, a display signal necessary for the display portion to perform display, a drive voltage for a display drive circuit modularized with a display element, and the like need to be transmitted from the body portion to the display portion using a connection wire.

The configuration shown in FIG. 5 is known (see JP H3-116211A) as technology for preventing, in the case where the display portion is allowed to be pivoted by the hinge mechanism with respect to the body portion, strain to a connection wire that connects the body portion with the display portion from being subjected to strain due to the pivot using the hinge mechanism.

In an information device 500 shown in FIG. 5, which is a conventional electronic device, a display portion 501 having a display panel 504 and a body portion 502 on which a keyboard and the like (not shown) are disposed are integrated by a hinge mechanism 509 so as to be pivotable about a pivot axis X′. A flexible cable 505 led out of the display portion 501 in order to connect a drive circuit board (not shown) of the display panel 504 in the display portion 501 with a main circuit board (not shown) in the body portion 502 passes through a hollow portion of the hinge mechanism 509, and is connected to a connection terminal 508 provided on the surface of the body portion 502 for the connection to the main circuit board in the body portion 502. As shown in FIG. 5, the flexible cable 505 is pulled out from the hollow portion of the hinge mechanism 509, and thereafter the direction thereof is bent at a flexion portion, and the flexible cable 505 is connected to the connection terminal 508.

With the technology described in the above patent document, with regard to the information device constituted by two casings, that is, the display portion and the body portion, the flexible cable 505 serving as a connection wire is bent almost 90 degrees at the flexion portion so as to be oriented in the direction of the pivot axis of the hinge mechanism 509, and is pulled in the display portion from the body portion via the hollow portion in the hinge mechanism 509. This relaxes the torsion of the flexible cable 505 relative to the pivot of the display portion, which improves the durability of the flexible cable 505.

However, with the conventional information device shown in FIG. 5, excessive load is applied to the connection wire due to the display portion being pivoted every time the information device is used, and thus a configuration is not realized in which it is possible to sufficiently avoid the occurrence of problems such as breaking of the connection wire due to long-term use or highly-frequent use.

### SUMMARY OF THE INVENTION

Therefore, with the foregoing in mind, it is an object of the present invention to provide an electronic device having a configuration in which breaking of a connection wire and the like are not likely to occur even if a first casing is pivoted with respect to a second casing regularly.

In order to solve the above problem, in an electronic device disclosed in this application, a first casing including a first electric circuit and a second casing including a second electric circuit are pivotably integrated by a hinge mechanism, and a connection wire that connects the first electric circuit with the second electric circuit is led from the inside of the second casing into a hinge portion in which the hinge mechanism is housed, and in the hinge portion, the connection wire forms a detour portion having a first direction component that is oriented in a first direction parallel to a pivot axis of the hinge mechanism and a second direction component that is oriented in a second direction parallel to the pivot axis and opposite to the first direction, and thereafter is led out of the hinge portion into the first casing.

In the electronic device disclosed in this application, the connection wire forms the detour portion inside the hinge portion where the hinge mechanism that connects the first casing with the second casing is housed, and thereafter is led out of the hinge portion into the first casing, and thus a great torsion force is not likely to be applied to the connection wire even if the first casing is pivoted. Accordingly, it is possible to obtain an electronic device in which breaking of the connection wire and the like are not likely to occur even if the first casing is pivoted with high frequency.

### BRIEF DESCRIPTION OF THE DRAWINGS

FIG. 1 is a perspective view showing the overall configuration of a notebook computer according to an embodiment of the present invention.

FIG. 2 is an enlarged perspective view of relevant parts showing an example of a configuration of a hinge portion in which a hinge mechanism is housed in the notebook computer according to the embodiment of this invention.

FIG. 3A is a diagram for illustrating the shape of a detour portion formed by a connection wire in the notebook computer according to the embodiment of this invention, showing a case where the detour portion is U-shaped.

FIG. 3B is a diagram for illustrating the shape of the detour portion formed by the connection wire in the notebook computer according to the embodiment of this invention, showing a case where the detour portion is horseshoe-shaped.

FIG. 3C is a diagram for illustrating the shape of the detour portion formed by the connection wire in the notebook computer according to the embodiment of this invention, showing a case where the detour portion is formed in a horizontal plane.

FIG. 3D is a diagram for illustrating the shape of the detour portion formed by the connection wire in the notebook computer according to the embodiment of this invention, showing a case where the detour portion is formed by a three-dimensional curved line.

FIG. 3E is a diagram for illustrating the shape of the detour portion formed by the connection wire in the notebook computer according to the embodiment of this invention, showing a case where the detour portion is spirally shaped.

FIG. 4 is an enlarged perspective view of relevant parts showing another example of a configuration of the hinge portion in which the hinge mechanism is housed in the notebook computer according to the embodiment of this invention.

FIG. 5 is an enlarged perspective view of relevant parts showing the configuration of a hinge mechanism portion in a conventional information device.

### DETAILED DESCRIPTION OF THE INVENTION

In an electronic device disclosed in this application, a first casing including a first electric circuit and a second casing including a second electric circuit are pivotably integrated by a hinge mechanism, and a connection wire that connects the first electric circuit with the second electric circuit is led from the inside of the second casing into a hinge portion in which the hinge mechanism is housed, and in the hinge portion, the connection wire forms a detour portion having a first direction component that is oriented in a first direction parallel to a pivot axis of the hinge mechanism and a second direction component that is oriented in a second direction parallel to the pivot axis and opposite to the first direction, and thereafter is led out of the hinge portion into the first casing.

In this way, torsion of the connection wire due to the pivot of the first casing with respect to the second casing is absorbed in the detour portion that has the first direction component oriented in the first direction parallel to the pivot axis of the hinge mechanism and the second direction component oriented in the second direction that is parallel to the pivot axis and opposite to the first direction, and thus a great torsion force is not likely to be directly applied to the connection wire. Further, since the connection wire passes through the detour portion in the course of the wire being led into the first casing from the second casing, the interval between fastening portions that each fasten the connection wire in the first casing and the second casing widens, and the force itself that affects the connection wire is reduced in the case where the torsion having the same angle occurs. Accordingly, it is possible to obtain an electronic device in which problems such as breaking of the connection wire are not likely to occur even if the first casing is repeatedly pivoted with respect to the second casing.

Note that in the description below in this specification, the direction of the connection wire is described considering the hinge portion as being the center, in a manner such that the connection wire is led into the hinge portion from the second casing and led out of the hinge portion into the first casing. However, this is merely an expression to facilitate the description, and thus it is to be understood that such an expression does not define a specific orientation of the actual connection wire, such as the procedure of disposing a connection wire in a method for manufacturing an electronic device, and the direction of electric signals that flow inside a connection wire, for example.

In the above-described electronic device disclosed in this application, it is preferable that the connection wire is led out of the hinge portion to the first casing in the second direction. In the configuration in which great torsion is applied to the connection wire if the first casing is pivoted, the influence of the torsion applied to the connection wire effectively can be reduced.

Further, it is preferable that the direction in which the connection wire is led into the hinge portion from the first casing and the direction in which the connection wire is led out of the hinge portion to the first casing are orthogonal to each other. The first casing can be superposed on the second casing, and thus the electronic device can be compactly folded.

Moreover, it is preferable that the pivot axis of the hinge mechanism is positioned above an upper face of the second casing, and the connection wire extends in a vertical direction relative to the upper face of the second casing, and is led into the hinge portion. In this way, the first electric circuit in the first casing and the second electric circuit in the second casing can be connected by the shortest connection wire.

Furthermore, it is preferable that the detour portion is a U-shaped portion in which the first direction component having a linear shape and the second direction component having a linear shape are connected by a curved line portion. In this way, the space where the detour portion is formed in the hinge portion can be reduced, and thus a highly reliable electronic device can be obtained without resulting in an increase in the size of the hinge portion.

Further, it is preferable that after forming the detour portion, the connection wire passes through an extension of the pivot axis of the hinge mechanism, and is led out of the hinge portion into the first casing. The connection wire passes along the extension line of the pivot axis of the hinge mechanism, and thereby deformation applied to the connection wire can be minimized.

Moreover, it is preferable that the first casing is a display portion that has a display panel, and the first electric circuit is a drive circuit that drives the display panel. In this way, it is possible to obtain an electronic device having an increased display size of the display portion.

Further, it is possible to obtain a notebook computer in which breaking of the connection wire is not likely to occur even if the display portion is opened and closed repeatedly, by adopting a configuration in which the second casing is a personal computer body portion including a keyboard for data input and a central integrated processing circuit.

Hereinafter, an electronic device of the present invention will be described by way of illustrative embodiments with reference to the drawings, using a notebook computer, as an example, in which a first casing includes a liquid crystal panel serving as a display panel, and a second casing serves as the body of the personal computer on which a keyboard is disposed.

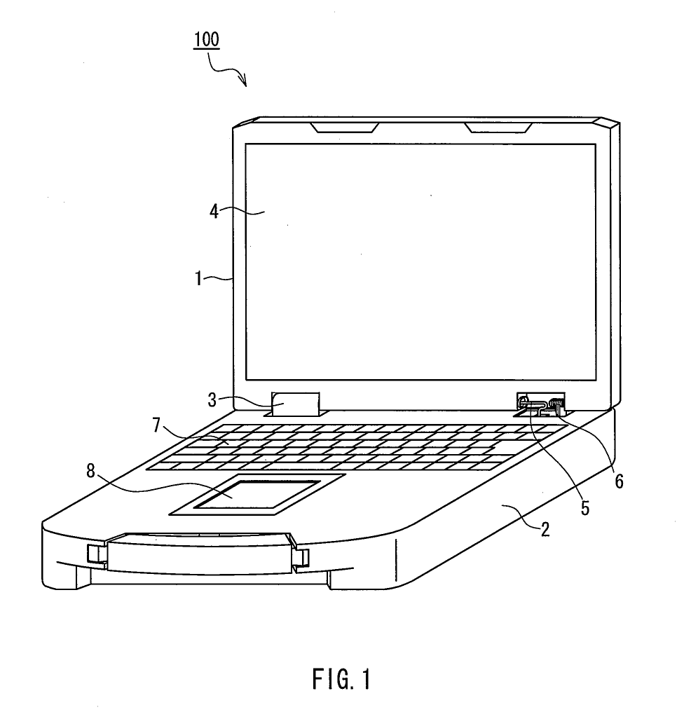

FIG. 1 is a perspective view showing the overall configuration of a notebook computer according to an embodiment of the present invention.

In a notebook computer 100 according to the present embodiment, a display portion 1 serving as a first casing is pivotably attached to a personal computer body portion 2 serving as a second casing, by hinge mechanisms each housed under a hinge portion cover 3.

The hinge mechanisms of the notebook computer 100 according to the present embodiment are provided so as to project upward from the inside of the personal computer body portion 2, such that the pivot axis thereof is positioned slightly above the upper face of the personal computer body portion 2. Further, two hinge mechanisms are disposed on both the right and left sides of the personal computer body portion 2 of the notebook computer 100 according to the present embodiment. Note that with regard to the notebook computer according to this embodiment, there are no restrictions on the disposing position of the hinge mechanism and the number of hinge mechanisms, and thus depending on the case where the number of hinge mechanisms is one or three or more, various configurations can be adopted, such as a state where the pivot shaft of the hinge mechanism is embedded inside the body and a state where the mechanism projects toward the rear of the body portion, rather than upward.

The display portion 1 houses a liquid crystal panel 4 serving as a display panel, and serves as a cover portion of the personal computer body portion 2 when the notebook computer 100 is not used. As the liquid crystal panel 4 housed in the display portion 1, an ordinary active matrix type liquid crystal panel can be used as an example, and the liquid crystal panel 4 is integrated with a backlight and a drive circuit for the liquid crystal panel 4 to perform image display, thereby constituting a liquid crystal module. In this way, a currently well-known configuration of a liquid crystal panel can be used as it is for the display panel, and thus a detailed description of the configuration of the display portion 1 including the liquid crystal panel 4 is omitted.

As an ordinary configuration as a notebook computer, a keyboard 7, a touchpad 8, a cover portion of a disk drive device (not shown), and the like are provided on the surface of the personal computer body portion 2. Circuit configurations such as a CPU and a memory, a rechargeable battery, various drive devices, and the like are housed in the personal computer body portion 2. A conventionally well-known configuration of a notebook computer is also applicable as it is to such a configuration of the personal computer body portions 2, and thus a detailed description thereof is omitted.

In FIG. 1, of the hinge mechanisms disposed on the right and left at the rear of the personal computer body portion 2, the cover of the hinge mechanism positioned on the right side has been removed, which shows a hinge shaft 6 that constitutes the hinge mechanism, and a connection wire 5 that is led into the hinge portion from the personal computer body portion 2, and thereafter led out of the hinge portion into the display portion 1. The connection wire 5 connects a display signal generating circuit serving as a second electric circuit and provided inside the personal computer body portion 2 with a drive circuit of the liquid crystal panel 4 serving as a first electric circuit and provided inside the display portion 1, for example. Note that the display signal generating circuit and the drive circuit are formed on their respective circuit boards, and the ends of the connection wire 5 are detachably attached to the circuit boards via connectors or the like.

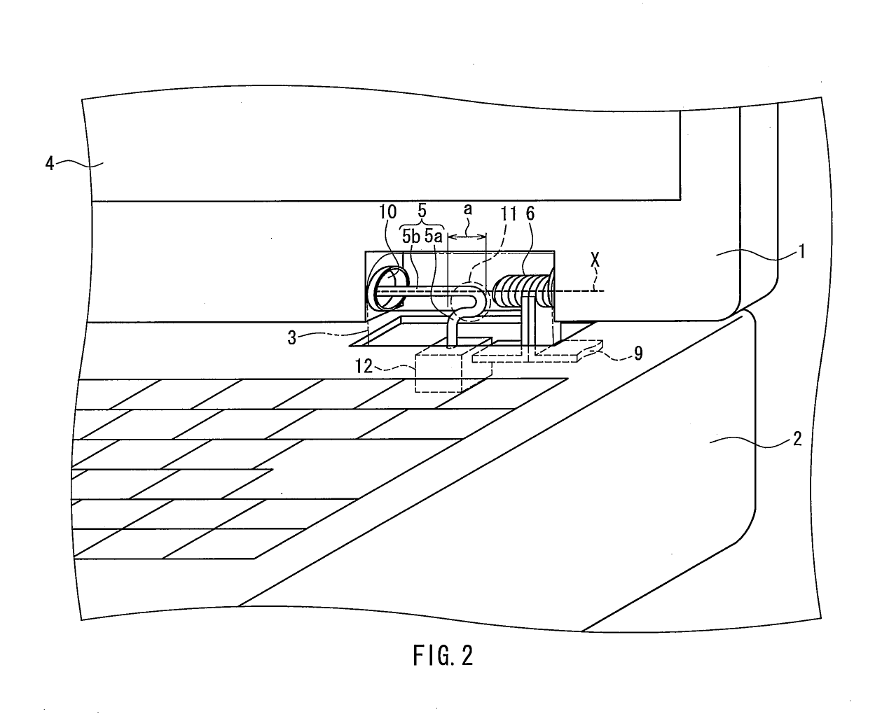

FIG. 2 is a partial enlarged perspective view showing the configuration of the hinge portion that connects the display portion 1 with the personal computer body portion 2 in the notebook computer 100 according to the present embodiment. Note that in FIG. 2 as well, the hinge portion is shown with the hinge portion cover 3 being removed in order to facilitate a description of the configuration of the hinge portion.

In the hinge portion of the notebook computer 100 according to the present embodiment, a hinge shaft support mechanism 9 formed in the personal computer body portion 2 and the hinge shaft 6 formed in the display portion 1 are housed, and the hinge mechanism is formed by the hinge shaft 6 and the hinge shaft support mechanism 9. The display portion 1 is attached so as to be pivotable about a pivot axis x, which is the center of the hinge shaft 6, with respect to the personal computer body portion 2. A cavity portion 10 is provided in a portion on the side where the hinge shaft 6 of the hinge portion is not formed, in other words, a portion on the left side in FIG. 2. The connection wire 5 that extends from the personal computer body portion 2 to the upper face thereof in the vertical direction and is led into the hinge portion passes through the cavity portion 10 and is led out of the hinge portion into the display portion 1 after the direction thereof is changed into the direction substantially orthogonal to the lead-in direction.

The portion of the connection wire 5 after a lead-in portion 5a where the wire is led into the hinge portion from the personal computer body portion 2 is not directly connected with a lead-out portion 5b where the wire is led out of the hinge portion into the display portion 1, but rather the connection wire 5 is bent once, in the hinge portion, in the direction parallel to the pivot axis x and opposite to the cavity portion 10 for leading the wire into the display portion 1, in other words, in the direction to the right in FIG. 2, which is the side where the hinge shaft 6 is formed. After that, the connection wire 5 is bent again in the direction in which the wire is led out of the hinge portion into the display portion 1 along the pivot axis x, in other words, in the direction of the cavity portion 10 on the left side in FIG. 2, and is led out of the hinge portion into the display portion 1 in this direction. In this way, the connection wire 5 forms a U-shaped detour portion 11 in which the axis parallel to the pivot axis x is set as being the longitudinal axis thereof in the hinge portion.

In the notebook computer 100 according to the present embodiment, the connection wire 5 forms the detour portion 11 in the hinge portion, and consequently a torsion force applied to the connection wire 5 in the case where the display portion 1 is pivoted using the hinge mechanism (6, 9) is absorbed by the deformation of the shape of the detour portion 11. Further, since the detour portion 11 is interposed in the course, the length of the connection wire 5 between a fastening portion (not shown) that determines the position of the connection wire 5 in the display portion 1 and a holder 12 that fixes the connection wire 5 in the personal computer body portion 2 is longer than that in the case where the detour portion 11 is not formed. Thus, the length of the connection wire 5 between the members that fix the connection wire 5 is longer, and thus if torsion is applied to the connection wire 5 by the pivot of the display portion 1, the amount of torsion per unit length of the connection wire 5 decreases. Accordingly, a force applied to the connection wire 5 due to the pivot of the display portion 1 decreases, and thus it is possible to obtain the highly-reliable notebook computer 100 in which breaking of the connection wire 5 and the like are not likely to occur even if the display portion 1 is pivoted with high frequency.

Note that the size of the detour portion 11 formed by the connection wire 5 is to be determined as appropriate, taking into consideration the thickness and the material of the connection wire 5, the size of the space in the hinge portion where the detour portion 11 is connected, and the like. In the case of the notebook computer 100 shown as an embodiment of the present invention, for example, the length of the detour portion 11 in the pivot-axis x direction shown by “a” in FIG. 2 can be set to 2 to 3 cm, and the interval between opposing portions of the connection wire 5 folded into an U shape can be set to 5 to 10 mm.

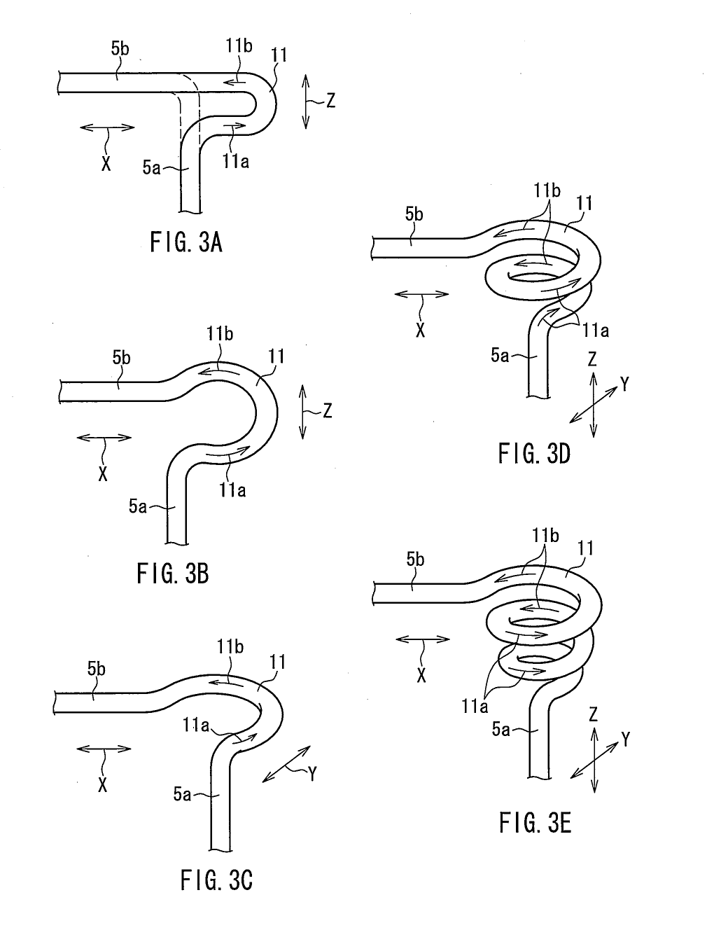

Here, various shapes that can be applied as the shape of the detour portion 11 are described in detail with reference to FIGS. 3A to 3E.

FIGS. 3A to 3E are diagrams illustrating shapes of the connection wire 5 that connects the second electric circuit in the personal computer body portion 2 with the first electric circuit provided inside the display portion 1 in the hinge portion of the notebook computer 100 according to the present embodiment. Note that in FIGS. 3A to 3E, only the connection wire 5 is illustrated, and the shapes thereof are shown, in order to avoid complication of the diagrams. Further, with regard to X, Y, and Z direction axes shown in FIGS. 3A to 3E, X represents an axis in the direction parallel to the pivot axis x of the hinge mechanism, Y represents an axis in the direction perpendicular to X, in other words, an axis in the direction parallel to the surface of the personal computer body portion 2, which is the horizontal axis when the notebook computer 100 is used, and Z represents an axis in the direction perpendicular to X and Y, in other words, an axis in the direction perpendicular to the surface of the personal computer body portion 2, which is the vertical axis when the notebook computer 100 is used.

FIG. 3A shows a state where the connection wire 5 described with reference to FIG. 2 forms the U-shaped detour portion 11 in the hinge portion. In the connection wire 5 of the notebook computer 100 according to the present embodiment, the lead-in portion 5a led into the hinge portion from the personal computer body portion 2 serving as the second casing is not directly connected with the lead-out portion 5b led out of the hinge portion into the display portion 1 serving as the first casing as shown by the dotted lines in FIG. 3A. The connection wire 5 of the notebook computer 100 according to the present embodiment forms, between the lead-in portion 5a and the lead-out portion 5b, the detour portion 11 that has a first direction component 11a that is a component in the X axis direction parallel to the hinge shaft from the lead-in portion 5a and is oriented in a first direction away from the lead-out portion 5b, and a second direction component 11b that is a component parallel to the X axis and is oriented in the direction opposite to the first direction component 11a. Note that in the detour portion 11 of the connection wire 5 shown in FIG. 3A, the first direction component 11a and the second direction component 11b have a substantially linear shape having a predetermined length, a curved line connects the first direction component 11a with the second direction component 11b, and the overall shape of the detour portion 11 is a U shape that leans to the left in FIG. 3A by 90 degrees.

Note that although FIG. 3A shows the state where the first direction component 11a and the second direction component 11b are accurately parallel to each other, the shape of the U-shaped detour portion 11 is not limited to this shape. It is sufficient that the first direction component and the second direction component each having a substantially linear shape are direction components that are oriented in the direction of the X axis and opposite to each other, and the detour portion 11 may have a U shape having an outspreading tip portion. Further, although FIG. 3A shows an example in which the U-shaped detour portion 11 is formed in a plane including the Z axis, the U-shaped detour portion 11 in the present embodiment is not limited only to an element formed in a plane including the Z axis as described above, and may have a U shape in a plane inclined at a predetermined angle relative to the Z axis, for example.

A space necessary for housing the detour portion 11 is the smallest if the detour portion 11 has a U shape as shown in FIG. 3A, and thus such a detour portion is particularly preferable as the detour portion 11 used for a portable device, for which there is a demand for a reduction in the entire size of a device including the hinge portion.

Next, FIG. 3B shows another example of a shape of the detour portion 11 formed in a plane in the Z axis direction, as with the case of the U-shaped detour portion 11 shown in FIG. 3A. FIG. 3B shows the detour portion 11 in which the first direction component 11a and the second direction component 11b are each formed by a curved line, not by a straight line, so as to have a horseshoe shape. Thus, in the detour portion 11 according to the present embodiment, it is sufficient that the first direction component 11a and the second direction component 11b are oriented in their own directions as a whole, and accordingly, the detour portion does not need to have a portion that is oriented linearly, as in the case of the U-shaped detour portion 11 shown in FIG. 3A.

In the case of the horseshoe-shaped detour portion 11 shown in FIG. 3B as well, the horseshoe shape itself is not rather important, but it is important that the detour portion 11 has the first direction component that is oriented once in the opposite direction, which means that the lead-in portion 5a and the lead-out portion 5b are not directly connected. In particular, in the case where a wire member used as the connection wire 5 is made of a soft material, or in the case of the detour portion 11 in which the distance allowed to be used for forming the first direction component 11a is short, it is also conceivable that the linear first direction component 11a and the linear second direction component 11b as in the U-shaped detour portion 11 cannot be formed, thus inevitably resulting in the horseshoe-shaped detour portion 11. Note that in the horseshoe-shaped detour portion 11 as well, the formation direction thereof is not limited in a plane including the Z axis, and it is sufficient that the detour portion 11 is formed in the Z axis direction as a whole, as with the case of the U-shaped detour portion 11 shown in FIG. 3A.

FIG. 3C shows an example in which the detour portion 11 is formed in the Y axis direction. Due to, for instance, restrictions on the arrangement of the hinge mechanism inside the hinge portion, if a space that allows the first direction component 11a to have a sufficient length in the X axis direction cannot be obtained as a space where the detour can be disposed in the hinge portion, there are cases where it is preferable to form the detour portion 11 in the direction of the horizontal axis Y, as shown in FIG. 3C.

Note that in the detour portion 11 formed in a horizontal direction and shown in FIG. 3C, the detour portion 11 does not need to be formed in a strictly horizontal plane, and may be formed in a plane intersecting the Y axis at a predetermined angle, as long as the detour portion is formed in a horizontal direction as a whole.

FIGS. 3D and 3E show cases where the detour portion 11 is formed by a three-dimensional curved line, that is, cases where the detour portion 11 is formed in a three-dimensional shape having X, Y, and Z direction components as the entire detour portion 11 having the first direction components 11a parallel to the X-axis and the second direction components 11b opposite thereto.

FIG. 3D shows a case where the detour portion 11 is formed by a plurality of curves each having substantially the same diameter, and FIG. 3E shows a case where the detour portion 11 has a spiral shape in which the diameter of curves decreases as they come closer to the lead-in portion 5a.

As shown in FIGS. 3D and 3E, in the case of the detour portion 11 having a three dimensional shape, the detour portion 11 has the plurality of first direction components 11a and the plurality of second direction components 11b. Thus, even if the display portion 1 is pivoted repeatedly with respect to the personal computer body portion 2, the detour portion 11 having a three dimensional shape can also prevent a great stress from being applied to the connection wire 5 by having the first direction components 11a and the second direction components 11b.

Although various examples of the shape of the detour portion 11 are shown in FIGS. 3A to 3E as described above, the shape of the detour portion 11 is not limited to these, and any shape can be used as long as the detour portion 11 has the first direction component and the second direction component between the lead-in portion 5a and the lead-out portion 5b. Regardless of the shape of the detour portion 11, as long as the lead-in portion 5a and the lead-out portion 5b are not directly connected in the hinge portion, and the detour portion 11 is provided that has the first direction component 11a and the second direction component 11b that are parallel to the pivot axis of the hinge mechanism and oriented in the directions opposite to each other, it is possible to reduce the influence of the external force applied to the connection wire 5 when the display portion 1 serving as the first casing is pivoted, and effectively avoid the occurrence of problems such as breaking of the connection wire 5.

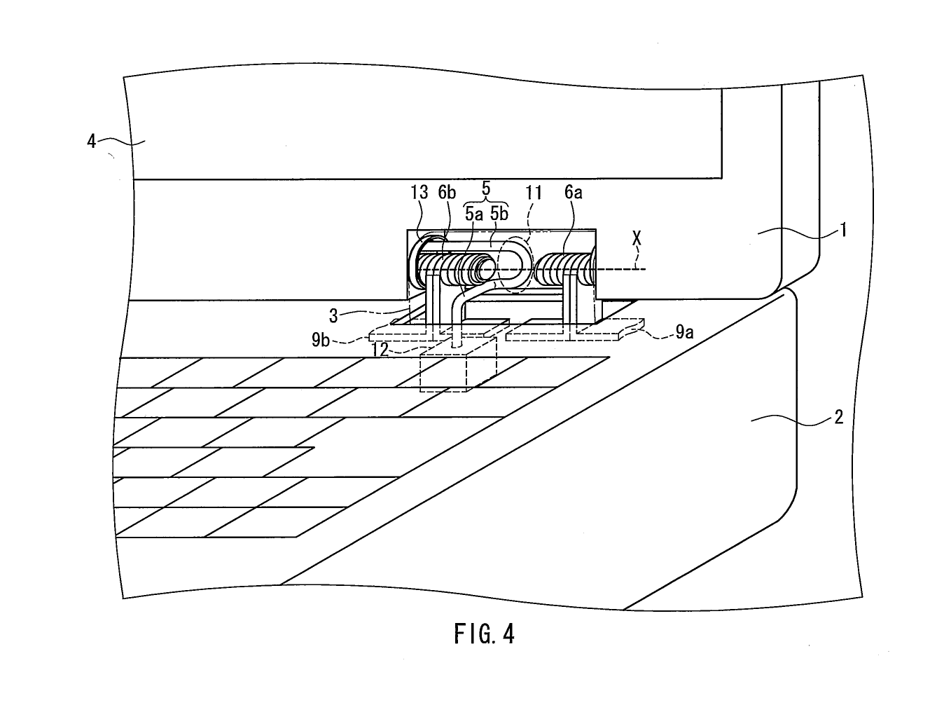

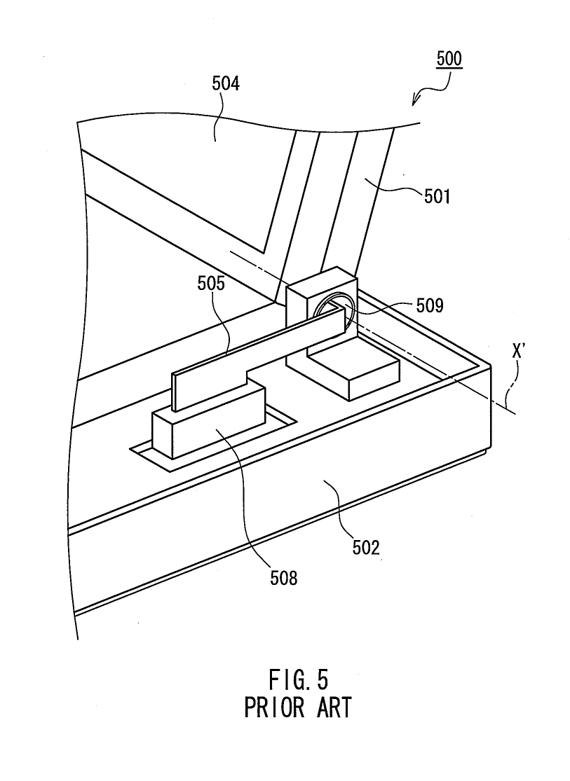

FIG. 4 is an enlarged perspective view of relevant parts showing another example of a configuration in the notebook computer 100 according to the present embodiment, in which the arrangement position of the connection wire 5 is different since the configuration of the hinge mechanism in the hinge portion is different.

In the hinge portion in another configuration example shown in FIG. 4, two hinge shaft support mechanisms 9a and 9b are formed in the personal computer body portion 2, and also two hinge shafts 6a and 6b are formed in the display portion 1, unlike the configuration shown in FIG. 2, and thus the hinge portion has two sets of hinge mechanisms (6a, 9a) and (6b, 9b). Accordingly, the connection wire 5 led into the hinge portion from the personal computer body portion 2 cannot be led out of the hinge portion along the pivot-axis x into the display portion 1. In view of this, as shown in FIG. 4, an opening 13 on the side of the hinge shaft 6b projecting from the center side of the display portion 1 has an oval shape extending upward, and the connection wire 5 is led out of the hinge portion into the display portion 1 from the extended portion of the opening 13.

Thus, in the notebook computer according to the present embodiment, the connection wire 5 is not necessarily led out of the hinge portion into the display portion 1 along the pivot axis x of the hinge shaft 6 (6a, 6b), and it is possible to prevent, by forming the detour portion 11 in the connection wire 5, breaking and the like from occurring due to application of strain to the connection wire 5. Note that in the case where the connection wire 5 cannot be led in along the pivot axis x, there are no restrictions on the direction in which the opening 13 extends so as to provide a lead-in portion of the connection wire 5, and the direction can be selected as appropriate based on the position and the size of the cavity in the hinge portion, the shape of the casing of the display portion 1, and the like.

Further, in the other configuration example shown in FIG. 4, since the two hinge mechanisms (6a, 9a) and (6b, 9b) are formed in the hinge portion, the holder 12 that fixes the connection wire in the personal computer body portion 2 is not directly under the hinge shafts (6a, 6b), and is disposed being slightly shifted to the side of the personal computer body portion 2 where the keyboard is formed. Due to the shift of the position of the holder 12 as described above, the connection wire 5 led into the hinge portion from the personal computer body portion 2 may incline slightly relative to an axis perpendicular to the surface of the body portion 2, compared with the case where the holder 12 is directly under the hinge shaft 6a as shown in FIG. 2. In such a case, for example, the entire detour portion 11 can be formed so as to be slightly inclined.

In this way, for example, even in the case where the connection wire cannot be led into the display portion from the hinge portion along the pivot axis, such as the case where two hinge shafts and two hinge shaft support mechanisms are provided in order to improve the strength of the hinge mechanism, it is possible to obtain a notebook computer in which breaking of the connection wire due to the pivot of the display portion and the like are not likely to occur, by providing the connection wire with a U-shaped portion in the hinge portion.

Although the above is a description of a notebook computer in which the first casing is the display portion provided with the liquid crystal panel serving as a display panel, and the second casing is the personal computer body portion, as the electronic device according to the present embodiment, this is merely an example and is not intended to limit applications thereof.

In the notebook computer according to the present embodiment, the display panel is not limited to a liquid crystal panel, and various display devices such as an organic electroluminescent panel can be used. Further, the electronic device according to the present embodiment is applicable to, other than a notebook computer, various devices such as a PDA, a mobile phone, and a portable game terminal, as a portable terminal in which a display portion is attached so as to be pivotable with respect to the body portion.

Moreover, the electronic device according to the present embodiment is not also limited to a device constituted by a display portion and a body portion, and the present invention is applicable to various devices in which a first casing is connected by a hinge mechanism so as to be pivotable with respect to a second casing, and a first electric circuit in the first casing and a second electric circuit in the second casing are connected by a connection wire. For example, the present invention also can be used for a keyboard for data input that can be folded for portable use, a keyboard of a foldable electric piano, and the like.

In a case of a keyboard that can be folded into three, for instance, the present invention is also applicable to an electronic device in which another casing further is pivotably connected by a hinge mechanism with at least one of a first casing and a second casing. In this case, a configuration is conceivable in which a hinge portion is disposed in various directions with respect to the first casing and the second casing, depending on the configuration of the electronic device, and as in the above-described example of the notebook computer, a case is also conceivable where the direction in which a connection wire is led into the hinge portion from the second casing and the direction in which the connection wire is led out of the hinge portion into the first casing are not orthogonal to each other. However, as described above, it is possible to effectively reduce, by forming the detour portion in the connection wire in the hinge portion, a harmful effect due to torsion applied to the connection wire when the first casing is pivoted with respect to the second casing.

In the description of the above embodiment, although the connection wire has been described and shown in the drawings as a connection cable having a substantially circular cross section, it is possible to use a parallel cable line in which a plurality of connection cables are linearly arranged as the connection wire, and also a flexible cable in which a metal wiring pattern such as a copper wiring pattern is formed on a base material made of resin.

As described above, the electronic device disclosed in this application is highly reliable in which breaking of the connection wire and the like are not likely to occur even if pivoting using the hinge mechanism is repeated, as an electronic device that has a first casing pivotably attached to a second casing by a hinge mechanism, and in which an electric circuit in the first casing and an electric circuit in the second casing are connected by a connection wire.

The electronic device disclosed in this application can be used for various electronic devices mainly for portable use.

The invention may be embodied in other forms without departing from the spirit or essential characteristics thereof. The embodiment disclosed in this application is to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. An electronic device comprising;
a first casing including a first electric circuit and a second casing including a second electric circuit are pivotably integrated by a hinge mechanism, and
a connection wire connecting the first electric circuit with the second electric circuit that is led from the inside of the second casing into a hinge portion in which the hinge mechanism is housed,
and in the hinge portion, the connection wire forms a detour portion having a first direction component that is oriented in a first direction parallel to a pivot axis of the hinge mechanism and a second direction component that is oriented in a second direction parallel to the pivot axis and opposite to the first direction, and thereafter is led out of the hinge portion into the first casing.

2. The electronic device according to claim 1, wherein the connection wire is led out of the hinge portion to the first casing in the second direction.

3. The electronic device according to claim 1, wherein the direction in which the connection wire is led into the hinge portion from the first casing and the direction in which the connection wire is led out of the hinge portion to the first casing are orthogonal to each other.

4. The electronic device according to claim 1, wherein the pivot axis of the hinge mechanism is positioned above an upper face of the second casing, and the connection wire extends in a vertical direction relative to the upper face of the second casing, and is led into the hinge portion.

5. The electronic device according to claim 1, wherein the detour portion is a U-shaped portion in which the first direction component having a linear shape and the second direction component having a linear shape are connected by a curved line portion.

6. The electronic device according to claim 1, wherein after forming the detour portion, the connection wire passes through an extension of the pivot axis of the hinge mechanism, and is led out of the hinge portion into the first casing.

7. The electronic device according to claim 1, wherein the first casing is a display portion that has a display panel, and the first electric circuit is a drive circuit that drives the display panel.

8. The electronic device according to claim 7, wherein the second casing is a personal computer body portion including a keyboard for data input and a central integrated processing circuit.
